(19) United States
(12) Patent Application Publication
(10) Pub. No.: US 2026/0165122 A1
(43) Pub. Date: Jun. 11, 2026

(54) SEMICONDUCTOR PACKAGE AND METHOD OF MANUFACTURING THE SAME

(71) Applicant: Samsung Electronics Co., Ltd., Suwon-si (KR)

(72) Inventors: Gunhyuck LEE, Suwon-si (KR); Kitae PARK, Suwon-si (KR); Seungmin BAEK, Suwon-si (KR); Yong Jae SONG, Suwon-si (KR)

(73) Assignee: Samsung Electronics Co., Ltd., Suwon-si (KR)

(21) Appl. No.: 19/369,481

(22) Filed: Oct. 27, 2025

(30) Foreign Application Priority Data
Dec. 6, 2024 (KR) 10-2024-0180871

(51) Int. Cl. H01L 23/367; H01L 21/311; H01L 21/48; H01L 21/56; H01L 23/00; H01L 23/31; H01L 23/538; H01L 23/544; H01L 25/065; H01L 25/18; H10B 80/00; H10D 80/30

(52) U.S. Cl. CPC H10W 40/228; H10P 50/282; H10P 50/73; H10W 46/00; H10W 70/02; H10W 70/611; H10W 70/65; H10W 74/01; H10W 74/137; H10W 90/00; H10B 80/00; H10D 80/30; H10W 46/301; H10W 72/01951; H10W 72/285; H10W 72/823; H10W 72/932; H10W 72/9415; H10W 72/942; H10W 72/944; H10W 72/9445; H10W 90/288; H10W 90/297; H10W 90/722; H10W 90/724

(57) ABSTRACT

A semiconductor package may include a vertically stacked semiconductor chips including semiconductor chips vertically stacked on each other, wherein at least one of the semiconductor chips may include a semiconductor substrate, a passivation pattern on a first surface of the semiconductor substrate, through vias in the semiconductor substrate and passing through the passivation pattern, heat dissipation pattern structure between the through vias and each filling one of heat dissipation trenches defined in the passivation pattern, and an alignment key filling an alignment trench defiled in the passivation pattern, and a level of a bottom surface of the alignment trench may be same as a level of bottom surfaces of the heat dissipation trenches.

### CROSS-REFERENCE TO RELATED APPLICATION(S)

This U.S. non-provisional application claims priority under 35 USC § 119 to Korean Patent Application No. 10-2024-0180871, filed on Dec. 6, 2024, in the Korean Intellectual Property Office, the disclosure of which is herein incorporated by reference in its entirety.

### BACKGROUND

The present disclosure relates to semiconductor packages and methods of manufacturing the same, and example, to semiconductor packages having stacked semiconductor chips and methods of manufacturing the same.

Recently, as the demand for semiconductor packages (e.g., high bandwidth memory (HBM)) has rapidly increased in various industries, various methods for improving the integration of the semiconductor packages are being researched. To this end, the size of semiconductor chips (e.g., memory chips) included in the semiconductor package has been miniaturized, and the spacing between the semiconductor chips has gradually decreased. However, there is a problem that it is difficult to dissipate heat generated in the semiconductor chips due to the higher integration of the semiconductor packages. This causes a degradation in the performance of the semiconductor packages.

### SUMMARY

Some example embodiments of the present disclosure may provide semiconductor packages with improved electrical characteristics and/or methods of manufacturing the same.

Some example embodiments of the present disclosure may provide semiconductor packages with improved heat dissipation performance and/or methods of manufacturing the same.

Some example embodiments of the present disclosure may provide semiconductor packages with improved structural stability and/or methods of manufacturing the same.

Some example embodiments of the present disclosure may provide semiconductor packages with a simplified manufacturing process and/or reduced manufacturing costs and/or methods of manufacturing the same.

A semiconductor package according to one example embodiment of the present disclosure may include vertically stacked semiconductor chips including semiconductor chips vertically stacked on each other, wherein at least one of the semiconductor chips may include a semiconductor substrate, a passivation pattern formed on a first surface of the semiconductor substrate, through vias in the semiconductor substrate, the through vias passing through the passivation pattern, back pad structures on the through vias, the back pad structures exposed by the passivation pattern, and heat dissipation pattern structures between the back pad structures, and the heat dissipation pattern structures filling heat dissipation trenches defined in the passivation pattern, respectively, the heat dissipation pattern structures a same material as the back pad structures.

The at least one of the semiconductor chips may further include an alignment key filling an alignment trench defined in the passivation pattern, and a level of a bottom surface of the alignment trench may be same as levels of bottom surfaces of the heat dissipation trenches.

The alignment key may include a same material as the back pad structures.

The heat dissipation pattern structures and the alignment key may be on the passivation pattern.

The heat dissipation trenches and the alignment trench may be recessed from one surface of the passivation pattern to expose the semiconductor substrate, and the heat dissipation pattern structures and the alignment key may be on exposed portions of the semiconductor substrate.

The heat dissipation trench and the alignment trench may pass through the passivation pattern and may be recessed from the first surface of the semiconductor substrate to such that bottom surfaces of the heat dissipation trenches and a bottom surface of the alignment trench are in the semiconductor substrate.

The at least one of the semiconductor chips may further include barrier patterns provided between the heat dissipation pattern structures and the semiconductor substrate and between the alignment key and the semiconductor substrate.

The heat dissipation pattern structures may extend from the first surface of the semiconductor substrate to a second surface of the semiconductor substrate, the first surface of the semiconductor substrate and the second surface of the semiconductor substrate being opposite to each other, the heat dissipation pattern structures crossing the first surface of the semiconductor substrate.

The heat dissipation pattern structures may be exposed through side surfaces of the vertically stacked semiconductor chips.

The passivation pattern may include pad trenches, the pad trenches recessed from one surface of the passivation pattern and exposing the through vias, the back pad structures filling the pad trenches, respectively, and levels of bottom surfaces of the pad trenches may be same as levels of bottom surfaces of the heat dissipation trenches.

Spacing distances between the heat dissipation pattern structures and the back pad structures may be same.

The at least one of the semiconductor chips may include front pads, the front pads electrically connected to the through vias and being on a second surface of the semiconductor substrate that is opposite to the first surface of the semiconductor substrate.

The at least one of the semiconductor chips may include front heat dissipation patterns between the front pads, and a front passivation pattern on the second surface of the semiconductor substrate, the front passivation pattern exposing the front pads and the front heat dissipation patterns, the front pads of the at least one of the semiconductor chips may be in direct contact with the back pad structures of another one of the semiconductor chips, and the front heat dissipation patterns of the at least one of the semiconductor chips may be in direct contact with the heat dissipation pattern structure of the another one of the semiconductor chips.

The semiconductor package may further include a base chip under the vertically stacked semiconductor chips, wherein the base chip may include a base substrate, a base passivation pattern on one surface of the base substrate, base vias in the base substrate, the base vias passing through the base passivation pattern, base back pad structures on the base vias exposed by the base passivation pattern, and base heat dissipation pattern structure between the base back pads, the base heat dissipation pattern structure filling base heat dissipation trenches defined in the base passivation pattern, respectively, and the base heat dissipation pattern structures including a same material as the base back pad structures.

A method of manufacturing a semiconductor package according to one example embodiment of the present disclosure may include preparing a semiconductor die having through vias, etching the semiconductor die to expose the through vias, forming a passivation film on the semiconductor die so that the through vias are exposed through the passivation film, forming heat dissipation trenches in the passivation film by performing an etching process, forming back pad structures on the through vias, and forming heat dissipation pattern structures to fill the heat dissipation trenches, wherein the forming the back pad structures and the forming the heat dissipation pattern structures are simultaneously performed.

The forming of the heat dissipation trenches may include forming a first mask pattern including first openings defining the heat dissipation trenches and a second opening defining an alignment trench on the passivation film, and etching the passivation film using the first mask pattern as an etching mask to form the heat dissipation trenches and the alignment trench.

The method of manufacturing a semiconductor package may further include planarizing the passivation film to form a planarized passivation film, the planarized passivation film exposing the through vias thereby, wherein the forming of the back pad structures may include forming a conductive film on the planarized passivation film, the conductive film filling the heat dissipation trenches and the alignment trench, forming a second mask pattern having pad openings vertically overlapping the through vias, heat dissipation openings vertically overlapping the heat dissipation trenches, and an alignment opening vertically overlapping the alignment trench on the conductive film, forming conductive patterns on the conductive film exposed by the pad openings, the heat dissipation openings, and the alignment opening, and forming the back pad structures, the heat dissipation pattern structures, and an alignment key by etching the conductive film using the conductive patterns as an etching mask.

The forming of the heat dissipation trenches may include forming a third mask pattern including third openings and fourth openings, the third openings defining pad trenches that expose the through vias, the fourth openings defining the heat dissipation trenches on the passivation film, and etching the passivation film using the third mask pattern as an etching mask to form the heat dissipation trenches and the pad trenches.

The third mask pattern may further include a fifth opening defining an alignment trench, and when the heat dissipation trenches and the pad trenches are formed by etching the passivation film using the third mask pattern as the etching mask, the alignment trench may be further formed.

The forming of the back pad structures may include forming a conductive film on the passivation film on which the heat dissipation trenches and the pad trenches are formed, and inf the heat dissipation pattern structures and the back pad structures by planarizing the conductive film until the passivation film is exposed.

### BRIEF DESCRIPTION OF DRAWINGS

FIG. 1 is a plan view of a semiconductor package according to one example embodiment of the present disclosure.

FIG. 2 is a cross-sectional view taken along line I-I′ of FIG. 1.

FIG. 3A is a cross-sectional view of a semiconductor chip according to one example embodiment of the present disclosure.

FIG. 3B is a cross-sectional view of a semiconductor chip according to one example embodiment of the present disclosure.

FIG. 3C is a cross-sectional view of a semiconductor chip according to one example embodiment of the present disclosure.

FIG. 4 is a cross-sectional view of a base chip according to one example embodiment of the present disclosure.

FIG. 5 is a flowchart showing a method of manufacturing a semiconductor package according to one example embodiment of the present disclosure.

FIGS. 6 to 14C are cross-sectional views for showing a method of manufacturing a semiconductor package according to one example embodiment of the present disclosure, and are cross-sectional views corresponding to line I-I′ of FIG. 1.

FIG. 15 is a cross-sectional view of a semiconductor chip according to one example embodiment of the present disclosure.

FIG. 16 is a cross-sectional view of a semiconductor package according to one example embodiment of the present disclosure.

FIG. 17 is a cross-sectional view of a portion of a semiconductor package according to one example embodiment of the present disclosure.

FIG. 18 is a cross-sectional view of a portion of a semiconductor package according to one example embodiment of the present disclosure.

FIGS. 19 to 27 are cross-sectional views showing a method of manufacturing a semiconductor package according to one example embodiment of the present disclosure.

### DETAILED DESCRIPTION

Hereafter, some example embodiments of the present disclosure will be clearly and thoroughly described with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “one of,” “one or more of,” “any one of,” “at least one of,” and “at least one selected from” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

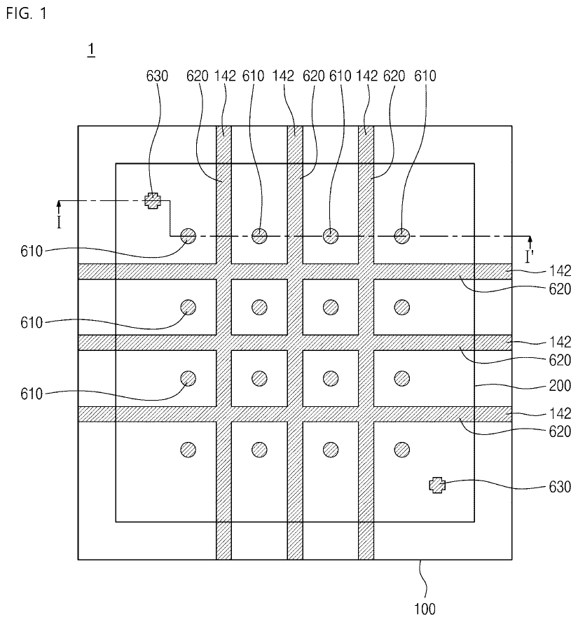

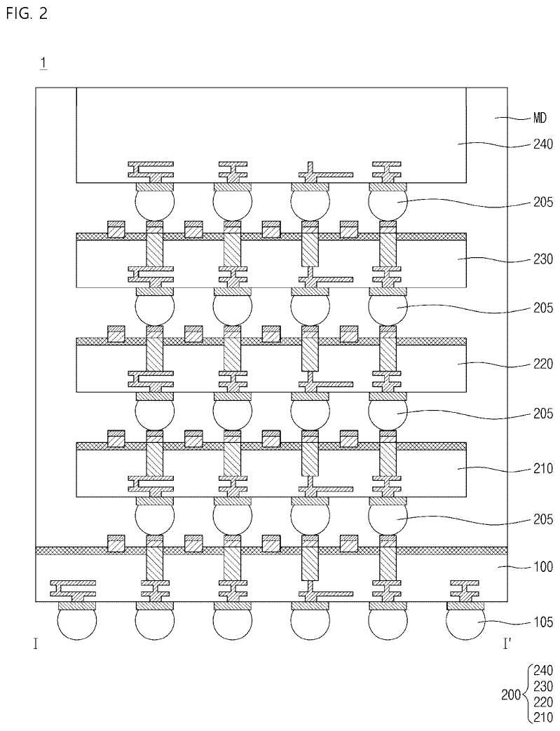

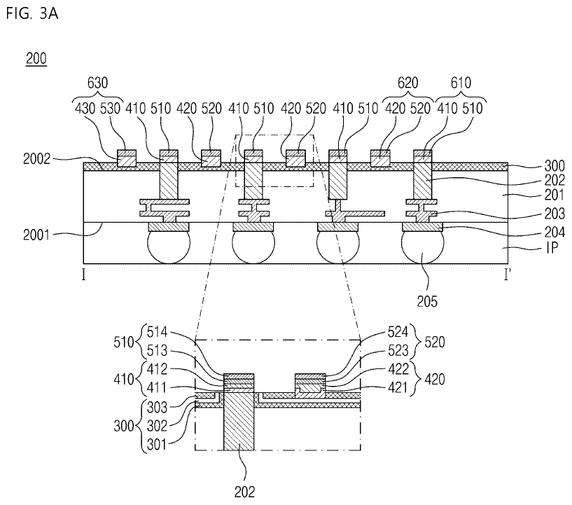

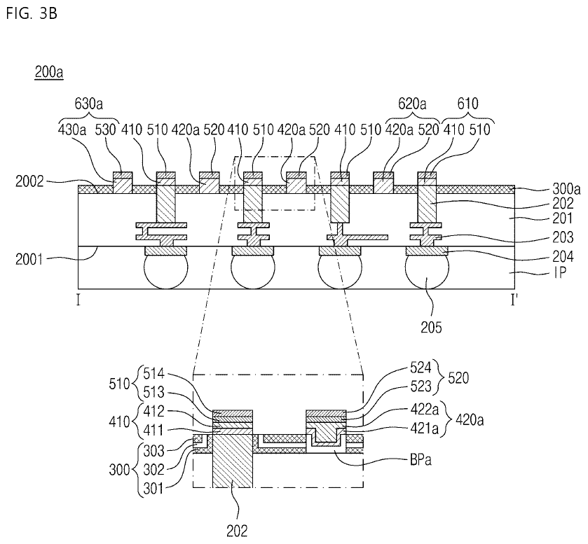

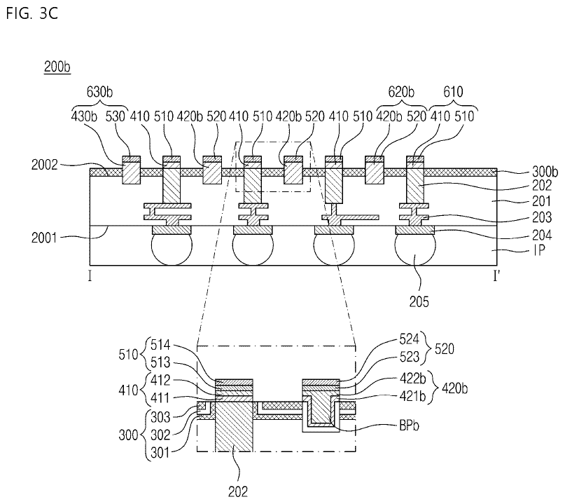

FIG. 1 is a plan view of a semiconductor package 1 according to one example embodiment of the present disclosure. FIG. 2 is a cross-sectional view taken along line I-I′ of FIG. 1. FIG. 3A is a cross-sectional view of a semiconductor chip 200 according to one example embodiment of the present disclosure.

Referring to FIGS. 1 and 2, the semiconductor package 1 may include a base chip 100, a plurality of semiconductor chips 200 vertically stacked on the base chip 100, and a mold MD provided on the base chip 100.

The base chip 100 may be provided under the stacked semiconductor chips 200. The base chip 100 may support the semiconductor chips 200. The base chip 100 may be referred to as a buffer chip, a logic chip, or an interposer. The base chip 100 may perform a controller function that controls the semiconductor chips 200.

External connection terminals 105 may be provided under the base chip 100. The external connection terminal 105 may be referred to as a solder ball, a bump, etc. The external connection terminals 105 may electrically connect the base chip 100 to an external device (not shown). That is, the external connection terminals 105 may electrically connect the semiconductor package 1 to an external device (not shown). The external connection terminals 105 may include a conductive material.

The semiconductor chips 200 may be mounted on the base chip 100 by a flip-chip method. For example, the semiconductor chips 200 may include a first semiconductor chip 210 on the base chip 100, a second semiconductor chip 220 on the first semiconductor chip 210, a third semiconductor chip 230 on the second semiconductor chip 220, and a fourth semiconductor chip 240 on the third semiconductor chip 230.

The semiconductor package 1 may include semiconductor chips 200 formed in a plurality of tiers. For example, the semiconductor package 1 may be provided in four tiers in which four semiconductor chips 200 are stacked, in eight tiers in which eight semiconductor chips 200 are stacked, twelve tiers in which twelve semiconductor chips 200 are stacked, sixteen tiers in which sixteen semiconductor chips 200 are stacked, etc. The semiconductor package 1 of this example embodiment is showed as being provided in four tiers for convenience, but is not limited thereto. Example embodiments of the present disclosure may be applied to a semiconductor package provided in eight tiers, twelve tiers, sixteen tiers, etc. in the same manner.

The semiconductor chips 200 may be electrically connected to each other. Internal connection terminals 205 may electrically connect the semiconductor chips 200 to each other. The internal connection terminal 205 may be referred to as a micro bump, etc. The internal connection terminal 205 may include a conductive material.

The internal connection terminals 205 may be provided between the semiconductor chips 200. The internal connection terminals 205 may come into contact with the semiconductor chips 200. For example, the internal connection terminals 205 may be provided between the first semiconductor chip 210 and the second semiconductor chip 220, between the second semiconductor chip 220 and the third semiconductor chip 230, and between the third semiconductor chip 230 and the fourth semiconductor chip 240. Therefore, the first to fourth semiconductor chips 210, 220, 230, and 240 may be electrically connected to each other.

The lowest semiconductor chip 200 among the semiconductor chips 200 may be electrically connected to the base chip 100. The lowest internal connection terminals 205 among the internal connection terminals 205 may electrically connect the lowest semiconductor chip 200 to the base chip 100. For example, the first semiconductor chip 210, which is the lowest semiconductor chip 200, may be electrically connected to the base chip 100 by the internal connection terminals 205.

A structure of the uppermost semiconductor chip 200 among the semiconductor chips 200 may differ from structures of the remaining semiconductor chips 200 among the semiconductor chips 200. For example, a thickness of the uppermost fourth semiconductor chip 240 may be larger than thicknesses of the remaining semiconductor chips 210, 220, and 230. The thicknesses of remaining semiconductor chips 210, 220, and 230 may be the same as or substantially similar to each other.

The mold MD may surround the stacked semiconductor chips 200. For example, the mold MD may cover side surfaces of the stacked semiconductor chips 200. the mold MD may extend between the stacked semiconductor chips 200. For example, the mold MD may extend between the first semiconductor chip 210 and the second semiconductor chip 220, between the second semiconductor chip 220 and the third semiconductor chip 230, and between the third semiconductor chip 230 and the fourth semiconductor chip 240. The mold MD may include an insulating polymer material. For example, the mold MD may include an epoxy molding compound (EMC).

Referring to FIG. 1 and FIG. 3A, the semiconductor chip 200 will be described in more detail. Here, the semiconductor chip 200 may be one of the remaining semiconductor chips 200, excluding the uppermost semiconductor chip 200 among the stacked semiconductor chips 200. That is, the description of a structure of the semiconductor chip 200 described below may be applied to at least one of the remaining semiconductor chips 200.

The semiconductor chip 200 may include a semiconductor substrate 201 having through vias 202, a passivation pattern 300 formed on one surface of the semiconductor substrate 201, back pad structures 610 on the through vias 202, heat dissipation pattern structures 620 between the back pads 610, and an alignment key 630.

The semiconductor substrate 201 may include a first surface 2001 and a second surface 2002. The first surface 2001 and the second surface 2002 may be opposite to each other. For example, the first surface 2001 of the semiconductor substrate 201 may be referred to as a front surface, and the second surface 2002 may be referred to as a back surface. Alternatively, the first surface 2001 of the semiconductor substrate 201 may be referred to as a bottom surface, and the second surface 2002 may be referred to as a top surface. The semiconductor substrate 201 may include silicon (Si), germanium (Ge), or silicon-germanium (SiGe).

The through vias 202 may pass through the semiconductor substrate 201. The through vias 202 may be electrically connected to circuit patterns 203 in the semiconductor substrate 201. The through vias 202 may protrude from one surface of the semiconductor substrate 201. The one surface of the semiconductor substrate 201 may be the second surface 2002. The through vias 202 may include a conductive material such as a metal. For example, the through vias 202 may include copper (Cu).

The circuit patterns 203 may include integrated circuits. For example, the circuit patterns 203 may include memory circuits, logic circuits, or a combination thereof. The circuit patterns 203 include a conductive material such as a metal.

The passivation pattern 300 may cover one surface of the semiconductor substrate 201. The passivation pattern 300 may expose one surfaces of the through vias 202. For example, the through vias 202 protruding from one surface of the semiconductor substrate 201 may pass through the passivation pattern 300, and one surfaces of the through vias 202 may be exposed through the passivation pattern 300.

The passivation pattern 300 may be provided in a structure of a single layer or multiple layers. The passivation pattern 300 may include at least one of a silicon oxide, a silicon nitride, or a silicon oxynitride.

In one example embodiment, the multi-layer passivation pattern 300 may include a first passivation pattern 301 on the semiconductor substrate 201, a second passivation pattern 302 on the first passivation pattern 301, and a third passivation pattern 303 on the second passivation pattern 302. For example, the first passivation pattern 301 may include a silicon oxide, the second passivation pattern 302 may include a silicon nitride, and the third passivation pattern 303 may include a silicon oxide.

In one example embodiment, the passivation pattern 300 may include at least one of the first passivation pattern 301, the second passivation pattern 302, or the third passivation pattern 303.

The back pad structures 610 may be provided on the through vias 202. For example, the back pad structures 610 may be provided on one surfaces of the through vias 202 exposed through the passivation pattern 300. The back pad structures 610 may come into contact with the through vias 202. The back pad structures 610 may be electrically connected to the through vias 202. The back pad structures 610 may include a conductive material such as metal. For example, the back pad structures 610 may include at least one of titanium (Ti), copper (Cu), nickel (Ni), or gold (Au).

The back pad structures 610 may be arranged to be spaced apart from each other on one surface of the semiconductor substrate 201. The back pad structures 610 may be arranged parallel to one side and another side of the semiconductor substrate 201 in a plan view. The another side of the semiconductor substrate 201 may be adjacent to the one side. The back pad structures 610 may be arranged in a matrix form on one surface of the semiconductor substrate 201. For example, the back pad structures 610 may be arranged in a 4×4 matrix form.

In one example embodiment, each of the back pad structures 610 may include a first back pad 410 provided on the through via 202 and a second back pad 510 on the first back pad 410. A material of the first back pad 410 may differ from a material of the second back pad 510. The first back pad 410 may come into contact with the through via 202, and the second back pad 510 may be electrically connected to the through via 202 through the first back pad 410.

In one example embodiment, the first back pad 410 may include a first pad pattern 411 on the through via 202 and a second pad pattern 412 on the first pad pattern 411. A material of the first pad pattern 411 may differ from a material of the second pad pattern 412. For example, the first pad pattern 411 may include one of titanium (Ti), copper (Cu), nickel (Ni), or gold (Au), and the second pad pattern 412 may include another one of titanium (Ti), copper (Cu), nickel (Ni), or gold (Au).

In one example embodiment, the second back pad 510 may include a third pad pattern 513 on the first back pad 410 and a fourth pad pattern 514 on the third pad pattern 513. A material of the third pad pattern 513 may differ from a material of the fourth pad pattern 514. For example, the third pad pattern 513 may include still another one of titanium (Ti), copper (Cu), nickel (Ni), or gold (Au), and the fourth pad pattern 514 may include the remaining one of titanium (Ti), copper (Cu), nickel (Ni), or gold (Au).

The heat dissipation pattern structures 620 may be provided between the back pads 610. The heat dissipation pattern structures 620 may be provided in the passivation pattern 300. The heat dissipation pattern structures 620 may protrude from one surface of the passivation pattern 300. For example, a portion of each of the heat dissipation pattern structures 620 may be provided in the passivation pattern 300, and the other portion may protrude from one surface of the passivation pattern 300. The heat dissipation pattern structures 620 may include the same or substantially similar material as the back pads 610. For example, the heat dissipation pattern structures 620 may include at least one of titanium (Ti), copper (Cu), nickel (Ni), or gold (Au).

The heat dissipation pattern structures 620 may cross one surface of the semiconductor substrate 201 in a plan view. The heat dissipation pattern structures 620 may cross a space between the back pad structures 610 in a plan view. For example, the heat dissipation pattern structures 620 may extend from one end of the semiconductor substrate 201 to the other end of the semiconductor substrate 201 that is opposite to the one end. Therefore, the heat dissipation pattern structures 620 may be exposed through the side surfaces of the semiconductor chip 200.

Some (e.g., two or more) of the heat dissipation pattern structures 620 may intersect the others of the heat dissipation pattern structures 620. Some (e.g., two or more) of the heat dissipation pattern structures 620 may extend parallel to one side of the semiconductor substrate 201, and the others of the heat dissipation pattern structures 620 may extend parallel to another side of the semiconductor substrate 201. Another side of the semiconductor substrate 201 may be adjacent to the one side. Therefore, the heat dissipation pattern structures 620 may be exposed through all side surfaces of the semiconductor chip 200.

The heat dissipation pattern structures 620 may be arranged in a direction intersecting the extended direction. The heat dissipation pattern structures 620 may be arranged at regular intervals from each other.

In one example embodiment, each of the heat dissipation pattern structures 620 may include a first heat dissipation pattern 420 on the passivation pattern 300 and a second heat dissipation pattern 520 on the first heat dissipation pattern 420. A material of the first heat dissipation pattern 420 may differ from a material of the second heat dissipation pattern 520. For example, the first heat dissipation pattern 420 may include the same or substantially similar material as the first back pad 410, and the second heat dissipation pattern 520 may include the same or substantially similar material as the second back pad 510.

In one example embodiment, the first heat dissipation pattern 420 may include a first heat dissipation layer 421 on the passivation pattern 300 and a second heat dissipation layer 422 on the first heat dissipation layer 421. A material of the first heat dissipation layer 421 may differ from a material of the second heat dissipation layer 422. For example, the first heat dissipation layer 421 may include the same material or substantially similar as the first pad pattern 411, and the second heat dissipation layer 422 may include the same or substantially similar material as the second pad pattern 412.

In one example embodiment, the second heat dissipation pattern 520 may include a third heat dissipation layer 523 on the first heat dissipation pattern 420 and a fourth heat dissipation layer 524 on the third heat dissipation layer 523. A material of the third heat 13 dissipation layer 523 may differ from a material of the fourth heat dissipation layer 524. For example, the third heat dissipation layer 523 may include substantially the same material as the third pad pattern 513, and the fourth heat dissipation layer 524 may include substantially the same material as the fourth pad pattern 514.

The alignment key 630 may be provided in the passivation pattern 300. The alignment key 630 may protrude from one surface of the passivation pattern 300. For example, a portion of the alignment key 630 may be provided in the passivation pattern 300, and the remaining portion of the alignment key 630 may protrude from one surface of the passivation pattern 300. The alignment key 630 may include the same or substantially similar material as the back pads 610. The alignment key 630 may include the same or substantially similar material as the heat dissipation pattern structures 620. For example, the alignment key 630 may include at least one of titanium (Ti), copper (Cu), nickel (Ni), or gold (Au).

The alignment key 630 may be adjacent to an edge of the semiconductor substrate 201 in a plan view. The alignment key 630 may be spaced apart from the heat dissipation pattern structures 620 and the back pads 610. A planar shape of the alignment key 630 may differ from planar shapes of the heat dissipation pattern structures 620. For example, the alignment key 630 may be provided in a cross shape.

However, a structure of the alignment key 630 other than the size and shape may be the same as or substantially similar to that of the heat dissipation pattern 620 in a cross-sectional view. That is, a stacking structure and stacking material of the alignment key 630 may be the same as or substantially similar to a stacking structure and stacking material of the heat dissipation pattern structures 620.

The semiconductor chip 200 may further include front pads 204 on the other surface of the semiconductor substrate 201. The front pads 204 may be electrically connected to the circuit patterns 203. The front pads 204 may be electrically connected to the through vias 202 through the circuit patterns 203. In one example embodiment, the internal connection terminals 205 may come into contact with one surface of the front pads 204.

An insulating pattern IP may be interposed between the semiconductor chips 200. The insulating pattern IP may be referred to as an underfill, an insulator, etc. The insulating pattern IP may couple the semiconductor chips 200. That is, the insulating pattern IP may include a bonding material that couples the semiconductor chips 200. The insulating pattern IP may be filled between the internal connection terminals 205. The insulating pattern IP may include a non-conductive film (NCF), a non-conductive paste (NCP), an insulating polymer, or an epoxy resin.

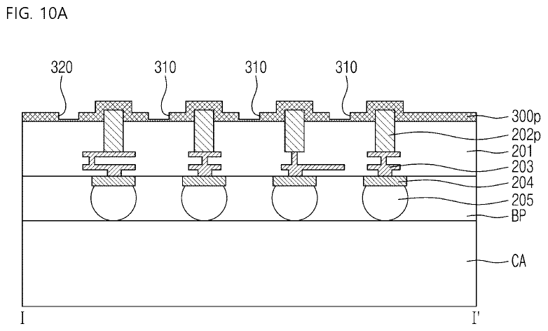

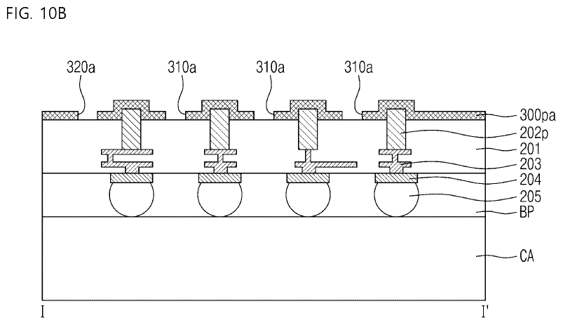

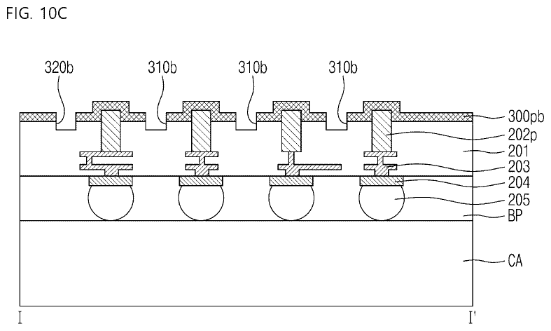

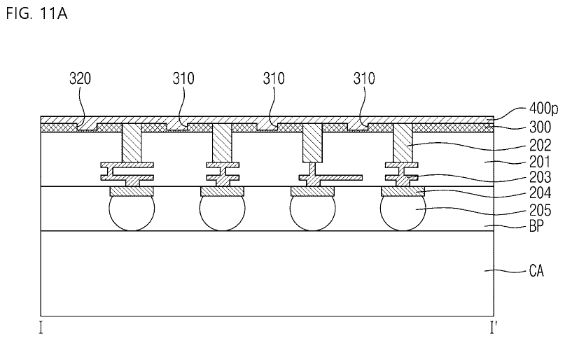

Referring to FIG. 3A, in one example embodiment, the heat dissipation pattern structures 620 may be provided on the passivation pattern 300. For example, a portion of each of the heat dissipation pattern structures 620 may be provided in the passivation pattern 300, and the remaining portion of each of the heat dissipation pattern structures 620 may protrude from the passivation pattern 300. Each of the heat dissipation pattern structures 620 may fill a heat dissipation trench 310 (see FIG. 10A) provided in the passivation pattern 300. The passivation pattern 300 may be formed so that the heat dissipation pattern structures 620 are spaced apart from the semiconductor substrate 201.

In one example embodiment, the alignment key 630 may be provided on the passivation pattern 300. For example, a portion of the alignment key 630 may be provided in the passivation pattern 300, and the remaining portion of the alignment key 630 may protrude from the passivation pattern 300. The alignment key 630 may fill an alignment trench 320 (see FIG. 10A) provided in the passivation pattern 300. The passivation pattern 300 may be formed so that the alignment key 630 is spaced apart from the semiconductor substrate 201.

A level of a bottom surface of the alignment trench 320 may be the same as or substantially similar to a level of a bottom surface of the heat dissipation trench 310. In other words, a level of a lower end of the alignment key 630 may be the same as or substantially similar to a level of a lower end of each of the heat dissipation pattern structures 620.

FIG. 3B is a cross-sectional view of a semiconductor chip 200a according to one example embodiment of the present disclosure.

Most components, which form the semiconductor chip 200a to be described below, and materials which form the components are the same as or substantially similar to the components and materials of the semiconductor chip 200 described above in FIG. 3A. Therefore, for convenience of explanation, differences from the above-described semiconductor chip 200 will be mainly described.

Referring to FIG. 3B, in one example embodiment, heat dissipation pattern structures 620a may be provided on the semiconductor substrate 201. For example, each of the heat dissipation pattern structures 620a may fill a heat dissipation trench 310a (see FIG. 10B) that exposes the semiconductor substrate 201. The heat dissipation trench 310a (see FIG. 10B) may pass through a passivation pattern 300a.

In one example embodiment, an alignment key 630a may be provided on the semiconductor substrate 201. For example, the alignment key 630a may fill an alignment trench 320a (see FIG. 10B) that exposes the semiconductor substrate 201. The alignment trench 320a (see FIG. 10B) may pass through the passivation pattern 300a.

The semiconductor chip 200a may further include barrier patterns BPa provided between the semiconductor substrate 201 and the heat dissipation pattern structures 620a. The barrier patterns BPa may be formed so that the semiconductor substrate 201 is spaced apart from the heat dissipation pattern structures 620a. The barrier patterns BPa may couple the heat dissipation pattern structures 620a and the alignment key 630a to the semiconductor substrate 201. The barrier patterns BPa may inhibit the diffusion of a material between the semiconductor substrate 201 and the heat dissipation pattern 620a and a material between the semiconductor substrate 201 and the alignment key 630a. For example, the barrier patterns BPa may include at least one of tantalum (Ta), titanium (Ti), or chromium (Cr).

FIG. 3C is a cross-sectional view of a semiconductor chip 200b according to one example embodiment of the present disclosure.

Most components, which form the semiconductor chip 200b to be described below, and materials which form the components are the same as or substantially similar to or similar to the components and materials of the semiconductor chip 200 described above in FIG. 3A. Therefore, for convenience of explanation, differences from the above-described semiconductor chip 200 will be mainly described.

Referring to FIG. 3C, in one embodiment, heat dissipation pattern structures 620b may be provided even in the semiconductor substrate 201. For example, each of the heat dissipation pattern structures 620b may fill a heat dissipation trench 310b (see FIG. 10C) recessed from one surface of the semiconductor substrate 201. In this case, the heat dissipation trenches 310b (see FIG. 10C) may pass through a passivation pattern 300b.

In one example embodiment, an alignment key 630b may be provided even in the semiconductor substrate 201. For example, the alignment key 630b may fill an alignment trench 320b (see FIG. 10C) recessed from one surface of the semiconductor substrate 201. In this case, the alignment trench 320b (see FIG. 10C) may pass through the passivation pattern 300b.

A barrier pattern BPb may be provided on inner surfaces of the heat dissipation trench 310b (see FIG. 10C). The barrier pattern BPb may be provided on inner surfaces of the alignment trench 320b (see FIG. 10C). The barrier patterns BPb may couple the heat dissipation pattern structures 620b and the alignment key 630b to the semiconductor substrate 201. The barrier pattern BPb may inhibit the diffusion of a material between the semiconductor substrate 201 and the heat dissipation pattern 620b and a material between the semiconductor substrate 201 and the alignment key 630b. For example, the barrier pattern BPb may include at least one of tantalum (Ta), titanium (Ti), or chromium (Cr).

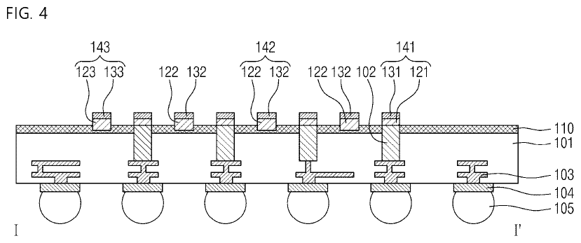

FIG. 4 is a cross-sectional view of a base chip 100 according to one example embodiment of the present disclosure.

Referring to FIG. 4, the base chip 100 will be described in more detail.

The base chip 100 may include a base substrate 101 having base vias 102, a base passivation pattern 110 formed on one surface of the base substrate 101, base back pad structures 141 on the base vias 102, base heat dissipation pattern structure 142 between the base back pad structures 141, and a base alignment key 143.

The base substrate 101 may include silicon, germanium, or silicon-germanium.

The base vias 102 may pass through the base substrate 101. The base vias 102 may be electrically connected to base circuit patterns 103 in the base substrate 101. The base vias 102 may protrude from one surface of the base substrate 101. The base vias 102 may include a conductive material such as a metal. For example, the base vias 102 may include copper (Cu).

The base passivation pattern 110 may cover one surface of the base substrate 101. The base passivation pattern 110 may expose one surface of the base vias 102. For example, the base vias 102 protruding from one surface of the base substrate 101 may pass through the base passivation pattern 110, and one surfaces of the base vias 102 may be exposed through the base passivation pattern 110.

A stacking structure of the base passivation pattern 110 may be the same as or substantially similar to that of the passivation pattern 300. A material of the base passivation pattern 110 may be the same as or substantially similar to that of the passivation pattern 300. For example, the base passivation pattern 110 may include a structure and a material corresponding to those of the passivation pattern 300 having at least one of the first to third passivation patterns 301, 302, and 303.

The base back pad structures 141 may be arranged to be spaced apart from each other on one surface of the base substrate 101. The base back pad structures 141 may be arranged parallel to one side and another side of the base substrate 101 in a plan view. Another side of the base substrate 101 may be adjacent to the one side. The base back pad structures 141 may be arranged in a matrix form on one surface of the base substrate 101. For example, the base back pad structures 141 may be arranged in a 4×4 matrix form.

A stacking structure of each of the base back pad structures 141 may be the same as or substantially similar to that of each of the back pad structures 610. The base back pad structures 141 may include substantially the same material as the back pad structures 610. For example, the base back pad 141 structures may include a first base back pad 121 and/or a second base back pad 131 that correspond to the first back pad 410 and/or the second back pad 510 of the back pad 610. In addition, the base back pad structures 141 may include a structure and a material corresponding to those of the back pad structures 610 having at least one of the first to fourth pad patterns 411, 412, 513, and 514.

The base heat dissipation pattern structures 142 may be provided between the base back pad structures 141. The base heat dissipation pattern structures 142 may be provided in the base passivation pattern 110. The base heat dissipation pattern structures 142 may protrude from one surface of the base passivation pattern 110. The base heat dissipation pattern structures 142 may include the same and substantially similar material as the base back pad structures 141. For example, the base heat dissipation patterns 142 may include at least one of titanium (Ti), copper (Cu), nickel (Ni), or gold (Au).

The base heat dissipation pattern structures 142 may cross one surface of the base substrate 101 in a plan view. The base heat dissipation pattern structures 142 may cross between the base back pad structures 141 in a plan view. For example, the base heat dissipation pattern structures 142 may extend from one end of the base substrate 101 to the other end of the base substrate 101 that are opposite to the one end. Therefore, the base heat dissipation pattern structures 142 may be exposed through side surfaces of the base chip 100.

Some (e.g., two or more) of the base heat dissipation pattern structures 142 may intersect the others of the base heat dissipation pattern structures 142. Some (e.g., two or more) of the base heat dissipation pattern structures 142 may extend parallel to one side of the base substrate 101, and the others of the base heat dissipation patterns 142 may extend parallel to another side of the base substrate 101. Another side of the base substrate 101 may be adjacent to the one side. Therefore, the base heat dissipation patterns 142 may be exposed through all side surfaces of the base chip 100.

The base heat dissipation pattern structures 142 may be arranged in a direction intersecting the extension direction of the base heat dissipation pattern structures 142. The base heat dissipation pattern structures 142 may be arranged at regular intervals from each other.

A stacking structure of each of the base heat dissipation pattern structures 142 may be the same as or substantially similar to that of each of the heat dissipation pattern structures 620. The base heat dissipation pattern structures 142 may include the same or substantially similar material as the heat dissipation pattern structure 620. For example, the base heat dissipation pattern structures 142 may include a first base heat dissipation pattern 122 and/or a second base heat dissipation pattern 132 that correspond to the first heat dissipation pattern 420 and/or the second heat dissipation pattern 520 of the heat dissipation pattern structures 620. In addition, the base heat dissipation pattern structures 142 may include a structure and a material corresponding to those of the heat dissipation pattern structures 620 having at least one of the first to fourth heat dissipation layers 421, 422, 523, and 524.

Each of the base heat dissipation patterns 142 may fill a base heat dissipation trench (no reference numeral assigned in FIG. 4) provided in the base passivation pattern 110. The base heat dissipation trench may be recessed from one surface of the base passivation pattern 110. The base heat dissipation trench may expose the base substrate 101. The base heat dissipation trench may also be provided in the semiconductor substrate 201.

The base alignment key 143 may be provided in the base passivation pattern 110. The base alignment key 143 may protrude from one surface of the base passivation pattern 110. The base alignment key 143 may include the same or substantially similar material as the base back pads 141. The base alignment key 143 may include the same or substantially similar material as the base heat dissipation patterns 142. For example, the base alignment key 143 may include at least one of titanium (Ti), copper (Cu), nickel (Ni), or gold (Au).

The base alignment key 143 may be adjacent to an edge of the base substrate 101 in a plan view. The base alignment key 143 may be spaced apart from the base heat dissipation patterns 142 and the base back pads 141. A planar shape of the base alignment key 143 may differ from planar shapes of the base heat dissipation patterns 142. For example, the base alignment key 143 may be provided in a cross shape.

However, a structure of the base alignment key 143 other than the size and shape may be the same as or substantially similar to that of the base heat dissipation pattern 142 in a cross-sectional view. That is, a stacking structure and stacking material of the base alignment key 143 may be the same as or substantially similar to the stacking structure and the stacking material of the base heat dissipation pattern 142.

The stacking structure of the base alignment key 143 may be the same as or substantially similar to that of the alignment key 630. The base alignment key 143 may include substantially the same material as the alignment key 630. For example, the base alignment key 143 may include a first base alignment pattern 123 and/or a second base alignment pattern 133 that correspond to the first alignment pattern 430 and/or the second alignment pattern 530 of the alignment key 630.

The base chip 100 may further include base front pads 104 on the other surface of the base substrate 101. The base front pads 104 may be electrically connected to the base circuit patterns 103. The base front pads 104 may be electrically connected to the base vias 102 through the base circuit patterns 103. In one example embodiment, external connection terminals 105 may come into contact with one surface of the base front pads 104.

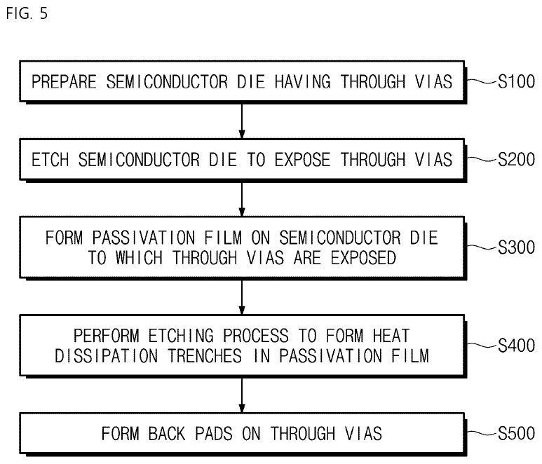

FIG. 5 is a flowchart showing a method of manufacturing the semiconductor package 1 according to one example embodiment of the present disclosure.

Referring to FIG. 5, the method of manufacturing the semiconductor package 1 (hereinafter, referred to as the “manufacturing method”) may include preparing a semiconductor die having through vias (S100), etching the semiconductor die to expose the through vias (S200), forming a passivation film on the semiconductor die, through which the through vias are exposed (S300), performing an etching process to form heat dissipation trenches in the passivation film (S400), and forming back pads on the through vias (S500). When the back pads are formed, heat dissipation patterns filling the heat dissipation trenches may be formed.

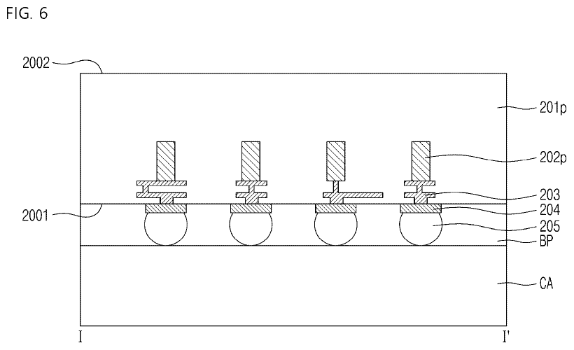

FIGS. 6 to 14C are cross-sectional views for showing a method of manufacturing the semiconductor package 1 according to one example embodiment of the present disclosure, and are cross-sectional views corresponding to line I-I′ of FIG. 1.

Referring to FIGS. 5 and 6, a semiconductor die 201p having preliminary through vias 202p may be prepared. The semiconductor die 201p may be coupled to a carrier CA by an adhesive pattern BP and flipped. The carrier CA may be coupled to a front surface of the semiconductor die 201p. The semiconductor die 201p may be flipped so that the first surface 2001, which is the front surface, faces downward. In this case, the second surface 2002, which is a back surface of the semiconductor die 201p, may face upward. Accordingly, subsequent processes may be performed on the back surface of the semiconductor die 201p.

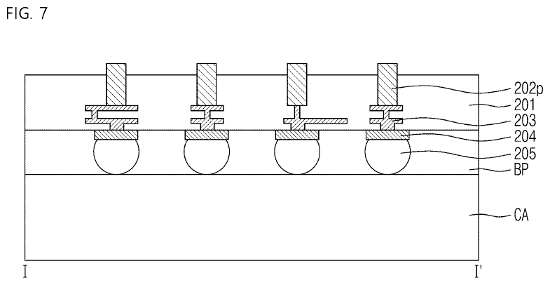

Referring to FIGS. 5 and 7, the semiconductor die 201p may be planarized until the preliminary through vias 202p are exposed. The semiconductor die 201p may be planarized to form the semiconductor substrate 201. For example, the planarization of the semiconductor die 201p may be performed by using an etch back process or a back grinding process. Thus, the preliminary through vias 202p may protrude from one surface of the semiconductor substrate 201.

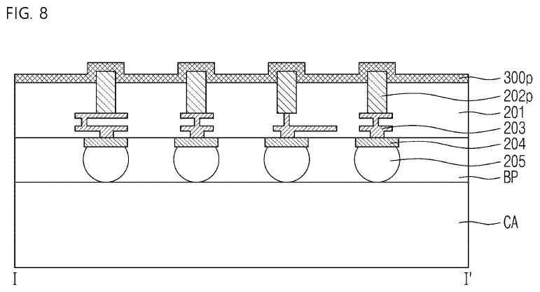

Referring to FIGS. 5 and 8, a passivation film 300p may be formed on one surface of the semiconductor substrate 201 to which the preliminary through vias 202p are exposed. The passivation film 300p may be conformally formed on one surface of the semiconductor substrate 201, through which the preliminary through vias 202p protrude. For example, the formation of the passivation film 300p may be performed by using a chemical-vapor deposition (CVD) process. Therefore, the passivation film 300p may also be conformally formed on the protruding preliminary through vias 202p.

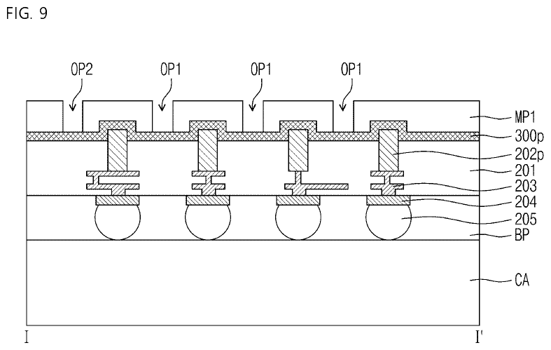

Referring to FIGS. 5 and 9, a first mask pattern MP1 having first openings OP1 and a second opening OP2 may be formed on the passivation film 300p. The first openings OP1 may define heat dissipation trenches 310, 310a, and 310b (see FIGS. 10A, 10B, and 10C). The second opening OP2 may define alignment trenches 320, 320a, and 320b (see FIGS. 10A, 10B, and 10C). The first mask pattern MP1 may cover the protruding preliminary through vias 202p.

Referring to FIGS. 5 and 10A to 10C, the passivation film 300p may be etched by using the first mask pattern MP1 as an etching mask. Portions of the passivation film 300p exposed through the first openings OP1 may be etched to form the heat dissipation trenches 310, 310a, and 310b. The other portions of the passivation film 300p exposed through the second opening OP2 may be etched to form the alignment trenches 320, 320a, and 320b. When the alignment trenches 320, 320a, and 320b are formed, the heat dissipation trenches 310, 310a, and 310b may be formed. Thus, levels of bottom surfaces of the alignment trenches 320, 320a, and 320b may be the same as or substantially similar to levels of bottom surfaces of the heat dissipation trenches 310, 310a, and 310b.

In one example embodiment as illustrated in FIG. 10B, heat dissipation trenches 310a and an alignment trench 320a may expose the semiconductor substrate 201. In this case, bottom surfaces of the heat dissipation trenches 310a and a bottom surface of the alignment trench 320a may be formed on one surface of the semiconductor substrate 201.

In one example embodiment as illustrated in FIG. 10C, the passivation film 300p and the semiconductor substrate 201 may be sequentially etched to form heat dissipation trenches 310b and an alignment trench 320b. The heat dissipation trenches 310b and the alignment trench 320b may pass through the passivation film 300pb and may be formed even in the semiconductor substrate 201. That is, bottom surfaces of the heat dissipation trenches 310b and a bottom surface of the alignment trenches 320b may be formed in the semiconductor substrate 201.

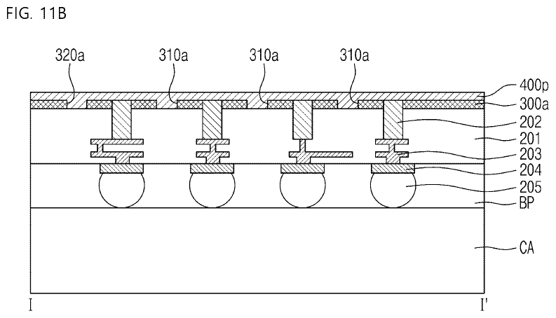

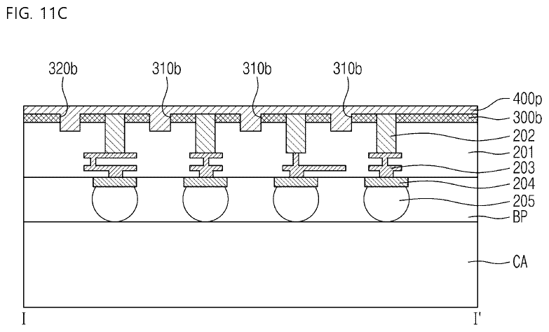

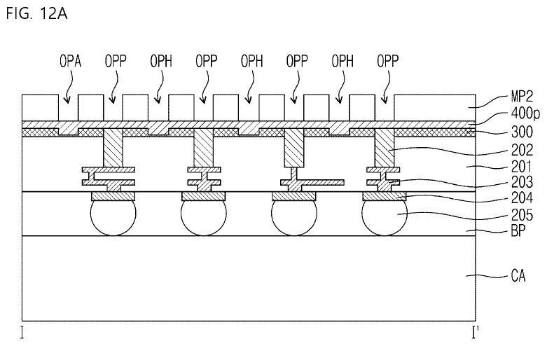

Referring to FIGS. 5 and 11A to 11C, the passivation films 300p, 300pa, and 300pb, in which the heat dissipation trenches 310, 310a, and 310b and the alignment trenches 320, 320a, and 320b are formed, may be planarized to form passivation patterns 300, 300a, and 300b. In addition, the preliminary through vias 202p covered by the passivation films 300p, 300pa, and 300pb may be planarized to form the through vias 202. For example, the planarization of the passivation films 300p, 300pa, and 300pb may be performed by using an etch-back process or a chemical mechanical polishing (CMP) process. The through vias 202 may be exposed by the passivation patterns 300, 300a, and 300b.

A conductive film 400p may be formed on the passivation patterns 300, 300a, and 300b. The conductive film 400p may fill the heat dissipation trenches 310, 310a, and 310b and the alignment trenches 320, 320a, and 320b. The conductive film 400p may also be formed on the through vias 202. Forming the conductive film 400p may include performing an electro-plating process on the planarized passivation patterns 300, 300a, and 300b. For example, the conductive film 400p may include plated copper (Cu).

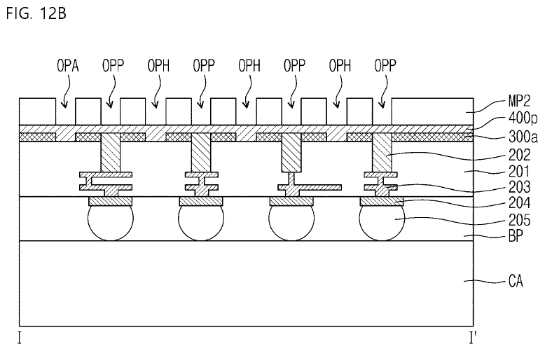

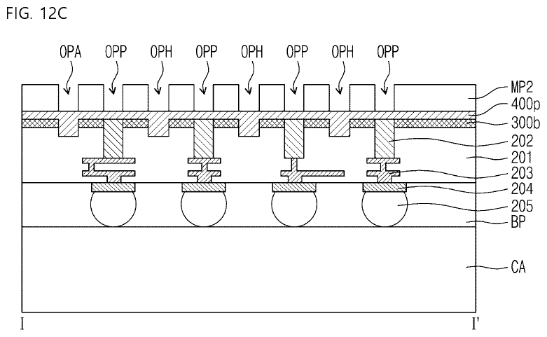

Referring to FIGS. 5 and 12A to 12C, a second mask pattern MP2 having pad openings OPP, heat dissipation openings OPH, and an alignment opening OPA may be formed on the conductive film 400p. The pad openings OPP may vertically overlap the through vias 202. The heat dissipation openings OPH may vertically overlap the heat dissipation trenches 310, 310a, and 310b. The alignment opening OPA may vertically overlap the alignment trenches 320, 320a, and 320b. The conductive film 400p may be exposed by the pad openings OPP, the heat dissipation openings OPH, and the alignment opening OPA.

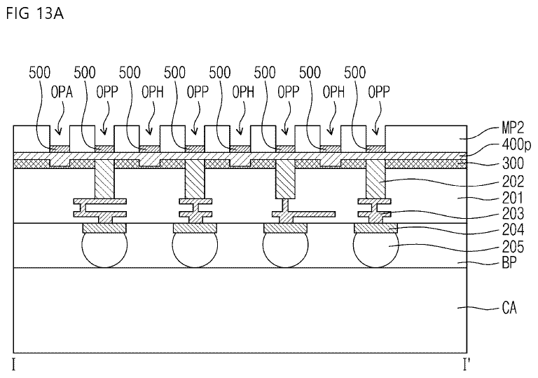

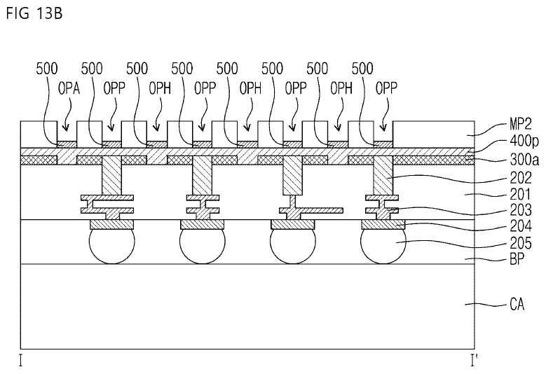

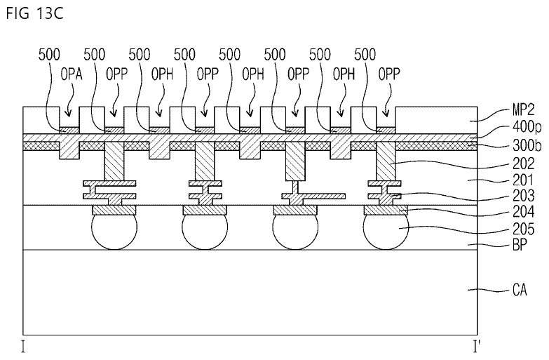

Referring to FIGS. 5 and 13A to 13C, conductive patterns 500 may be formed on the conductive film 400p exposed by the pad openings OPP, the heat dissipation openings OPH, and the alignment opening OPA. For example, the conductive patterns 500 may be formed over the through vias 202, the heat dissipation trenches 310, 310a, and 310b, and the alignment trenches 320, 320a, and 320b.

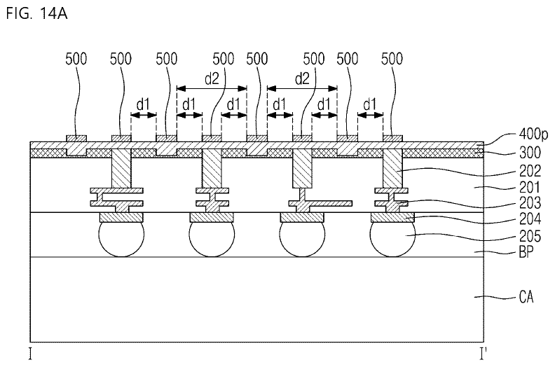

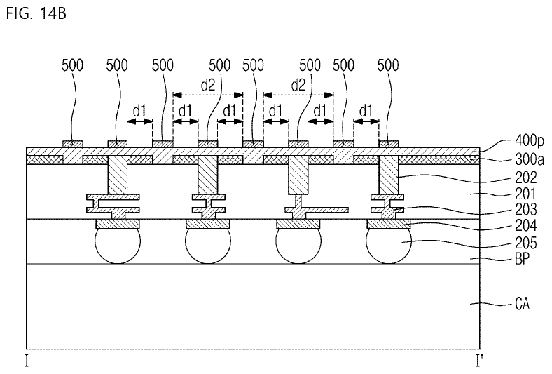

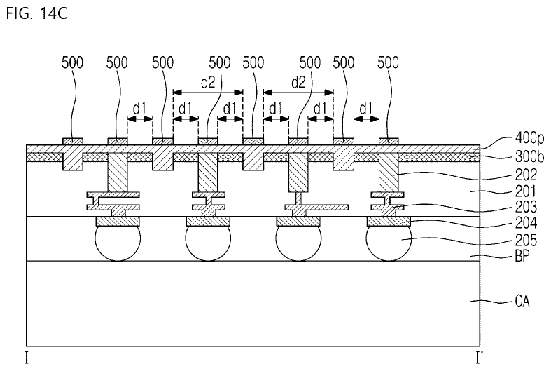

Referring to FIGS. 5 and 14A to 14C, after the conductive patterns 500 are formed, the second mask pattern MP2 may be removed. A blanket anisotropic etching process may be performed on the conductive film 400p by using the conductive patterns 500 as an etching mask. Accordingly, the back pad structures 610, the heat dissipation pattern structures 620, 620a, and 620b, and the alignment keys 630, 630a, and 630b may be formed. For example, the back pad structures 610 may be formed on the through vias 202, the heat dissipation pattern structures 620, 620a, and 620b may be formed on the heat dissipation trenches 310, 310a, and 310b, and the alignment keys 630, 630a, and 630b may be formed on the alignment trenches 320, 320a, and 320b. The conductive film 400p may form the first back pads 410, the first heat dissipation patterns 420, 420a, and 420b, and the first alignment patterns 430, 430a, and 430b. The conductive patterns 500 may each form the second back pads 510, the second heat dissipation patterns 520, and the second alignment pattern 530.

Spacing distances between the back pad structures 610 and the heat dissipation pattern structures 620 may be the same as or substantially similar to each other. For example, the back pad structures 610 may be spaced a first length d1 from the heat dissipation pattern structures 620.

Spacing distances between the neighboring heat dissipation pattern structures 620 may be the same as or substantially similar to each other. For example, the neighboring heat dissipation pattern structures 620 may be spaced a second length d2 from each other.

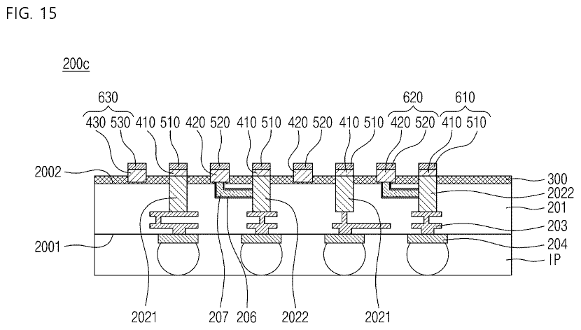

FIG. 15 is a cross-sectional view of a semiconductor chip 200c according to one example embodiment of the present disclosure.

Most components, which form the semiconductor chip 200c to be described below, and materials which form the components are the same as or substantially similar to or similar to the components and materials of the semiconductor chip 200 described above in FIGS. 3A to 3B. Therefore, for convenience of explanation, differences from the above-described semiconductor chip 200 will be mainly described.

Referring to FIG. 15, the semiconductor chip 200c may further include a heat transfer pattern 207 that connects the heat dissipation pattern 620 to the through vias 202. Some (e.g., two or more) among the through vias 202 may be thermal vias 2022 that vertically transfer heat, and the others among the through vias 202 may be signal vias 2021 that transfer an electrical signal. The heat transfer pattern 207 may connect the heat dissipation pattern 620 to the thermal via 2022. Therefore, heat transfer between the heat dissipation pattern 620 and the thermal via 2022 may be performed.

The heat transfer pattern 207 may be provided in the semiconductor substrate 201. The heat transfer pattern 207 may also pass through the passivation pattern 300. Therefore, the heat transfer pattern 207 may be connected to a lower surface of the heat dissipation pattern 620.

A barrier film 206 may be provided between the heat transfer pattern 207 and the semiconductor substrate 201. The barrier film 206 may be formed so that the heat transfer pattern 207 is spaced apart from the semiconductor substrate 201. The barrier film 206 may couple the heat transfer pattern 207 to the semiconductor substrate 201. The barrier film 206 may inhibit the diffusion of a material between the semiconductor substrate 201 and the heat transfer pattern 207. For example, the barrier film 206 may include at least one of tantalum (Ta), titanium (Ti), or chromium (Cr).

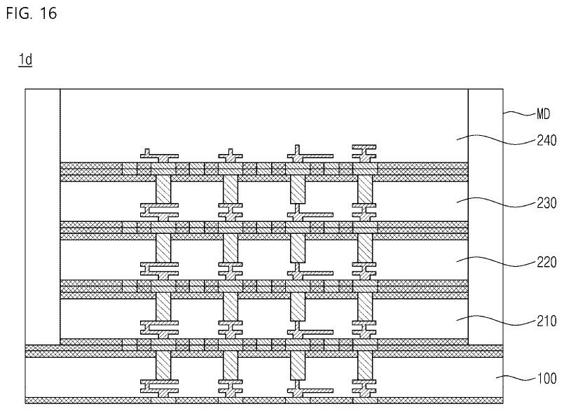

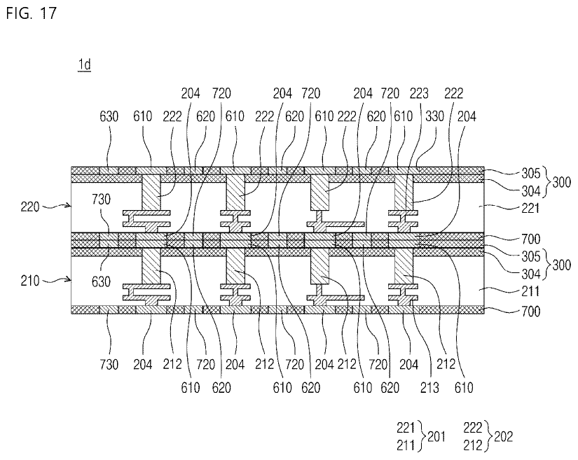

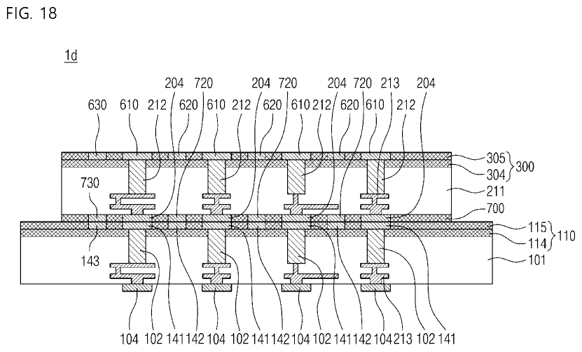

FIG. 16 is a cross-sectional view of a semiconductor package 1d according to one example embodiment of the present disclosure. FIG. 17 is a cross-sectional view of a portion of the semiconductor package 1d according to one example embodiment of the present disclosure. FIG. 18 is a cross-sectional view of a portion of the semiconductor package 1d according to one example embodiment of the present disclosure.

Most components, which form the semiconductor package 1d to be described below, and material which form the components are the same as or substantially similar to or similar to the components and materials of the semiconductor package 1 described above in FIGS. 1 to 4. Therefore, for convenience of explanation, differences from the above-described semiconductor package 1 will be mainly described.

Referring to FIGS. 16 and 17, in one example embodiment, the vertically stacked semiconductor chips 200 may come into direct contact with each other. For example, the front pads 204 of the second semiconductor chip 220 may come into direct contact with the back pad structures 610 of the first semiconductor chip 210.

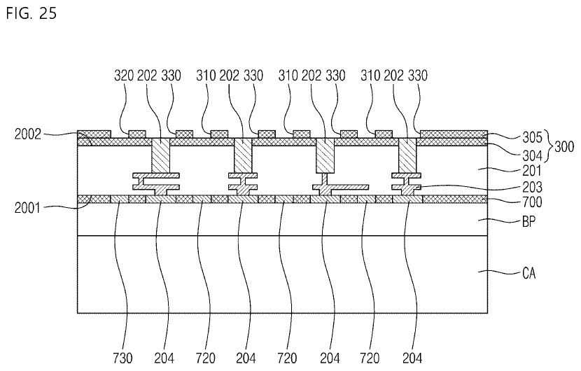

The back pad structures 610 may fill pad trenches 330 (see FIG. 25) provided in the passivation pattern 300. The pad trenches 330 may be recessed from one surface of the passivation pattern 300. The through vias 202 may be exposed by the pad trenches 330. The back pad structures 610filling the pad trenches 330 may be provided on the through vias 202.

For example, the passivation pattern 300 may include a sub-pattern 304 provided on one surface of the semiconductor substrate 201 and a cover pattern 305 provided on the sub-pattern 304. The through vias 202 may pass through the sub-pattern 304. The through vias 202 may be exposed through the sub-pattern 304.

The sub-pattern 304 may be provided in a single layer or multiple layers. The sub-pattern 304 may include at least one of a silicon oxide, a silicon nitride, or a silicon oxynitride. For example, the sub-pattern 304 may be provided in a dual-layer including a silicon oxide layer provided on the semiconductor substrate 201 and a silicon nitride layer on the silicon oxide layer.

The pad trenches 330 and the heat dissipation trenches 310 (see FIG. 25) may be provided in the cover pattern 305. The heat dissipation trenches 310 may be provided between the pad trenches 330. In one example embodiment, the alignment trench 320 (see FIG. 25) may be further provided in the cover pattern 305.

Levels of bottom surfaces of the heat dissipation trenches 310 may be the same as or substantially similar to levels of bottom surfaces of the pad trenches 330. In one example embodiment, a level of a bottom surface of the alignment trench 320 may be the same as or substantially similar to the levels of the bottom surfaces of the pad trenches 330 and/or the levels of the bottom surfaces of the heat dissipation trenches 310. For example, the bottom surfaces of the heat dissipation trenches 310 and the bottom surfaces of the pad trenches 330 may be formed on one surface of the sub-pattern 304. For example, the bottom surface of the alignment trench 320 may be formed on one surface of the sub-pattern 304.

The semiconductor chip 200 may further include front heat dissipation patterns 720 provided on the other surface of the semiconductor substrate 201. The front heat dissipation patterns 720 may be provided between the front pads 204. In some example embodiments, the front heat dissipation patterns 720 may come into direct contact with the heat dissipation pattern structures 620. For example, the front heat dissipation patterns 720 of the second semiconductor chip 220 may come into direct contact with the heat dissipation pattern structures 620 of the first semiconductor chip 210.

The semiconductor chip 200 may further include a front passivation pattern 700 provided on the other surface of the semiconductor substrate 201. The front heat dissipation patterns 720 and the front pads 204 may be exposed through the front passivation pattern 700. The front passivation pattern 700 may come into direct contact with the passivation pattern 300 such that, for example, the front passivation pattern 700 of the second semiconductor chip 220 comes into direct contact with the passivation pattern 300 of the first semiconductor chip 210.

The semiconductor chip 200 may further include an additional heat dissipation pattern 730 provided on the other surface of the semiconductor substrate 201. The additional heat dissipation pattern 730 may come into direct contact with the alignment key 630 such that, for example, the additional heat dissipation pattern 730 of the second semiconductor chip 220 comes into direct contact with the alignment key 630 of the first semiconductor chip 210.

Referring to FIGS. 16 and 18, the base back pad structures 141 may fill base pad trenches (no reference numeral assigned) provided in the base passivation pattern 110. The base pad trenches may be recessed from one surface of the base passivation pattern 110. The base vias 102 may be exposed by the base pad trenches. The base back pad structures 141 filling the base pad trenches may be provided on the base vias 102, respectively.

For example, the base passivation pattern 110 may include a base sub-pattern 114 provided on one surface of the base substrate 101 and a base cover pattern 115 provided on the base sub-pattern 114. The base vias 102 may pass through the base sub-pattern 114. The base vias 102 may be exposed through the base sub-pattern 114.

The base sub-pattern 114 may be provided in a single layer or multiple layers. The base sub-pattern 114 may include at least one of a silicon oxide, a silicon nitride, or a silicon oxynitride. For example, the base sub-pattern 114 may be provided in a dual-layer including a silicon oxide layer provided on the base substrate 101 and a silicon nitride layer on the silicon oxide layer.

The base pad trenches (no reference numeral assigned) and base heat dissipation trenches (no reference numeral assigned) may be provided in the base cover pattern 115. The base heat dissipation trenches may be provided between the base pad trenches. In one example embodiment, a base alignment trench may be further provided in the base cover pattern 115.

Levels of bottom surfaces of the base heat dissipation trenches (no reference numeral) may be the same as or substantially similar to levels of bottom surfaces of the base pad trenches (no reference numeral). In one example embodiment, a level of a bottom surface of the base alignment trench (no reference numeral) may be the same as or substantially similar to the levels of the bottom surfaces of the base pad trenches (no reference numeral) and/or the levels of the bottom surfaces of the base heat dissipation trenches (no reference numeral).

The lowermost semiconductor chip 200 among the semiconductor chips 200 may come into direct contact with the base chip 100. For example, the front pads 204 of the first semiconductor chip 210 may come into direct contact with the base back pads 141 of the base chip 100. The front heat dissipation patterns 720 of the first semiconductor chip 210 may come into direct contact with the base heat dissipation patterns 142 of the base chip 100. The front passivation pattern 700 of the first semiconductor chip 210 may come into direct contact with the base passivation pattern 110 of the base chip 100.

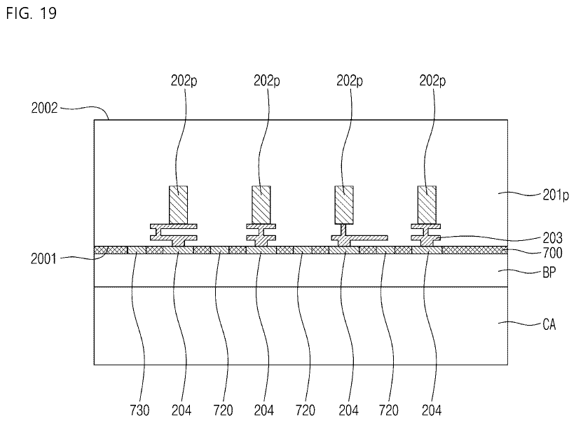

FIGS. 19 to 27 are cross-sectional views showing a method of manufacturing the semiconductor package 1d according to one example embodiment of the present disclosure.

Referring to FIG. 19, a semiconductor die 201p having preliminary through vias 202p may be prepared. The semiconductor die 201p may be coupled to a carrier CA by an adhesive pattern BP and flipped. The carrier CA may be coupled to a front surface of the semiconductor die 201p. The semiconductor die 201p may be flipped so that a first surface 2001, which is the front surface, faces downward. In this case, a second surface 2002, which is a back surface of the semiconductor die 201p, may face upward.

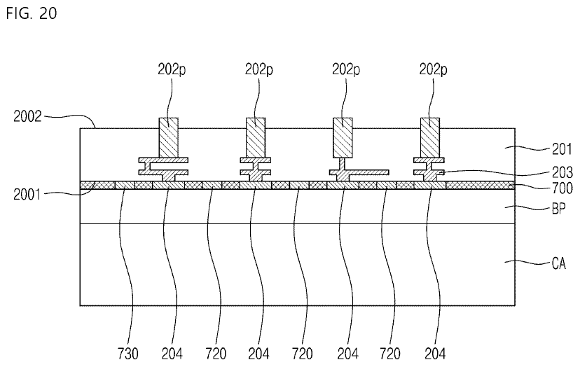

Referring to FIG. 20, the semiconductor die 201p may be planarized until the preliminary through vias 202p are exposed. The semiconductor die 201p may be planarized to form the semiconductor substrate 201. For example, the planarization of the semiconductor die 201p may be performed by using an etch back process or a back grinding process. Thus, the preliminary through vias 202p may protrude from one surface of the semiconductor substrate 201.

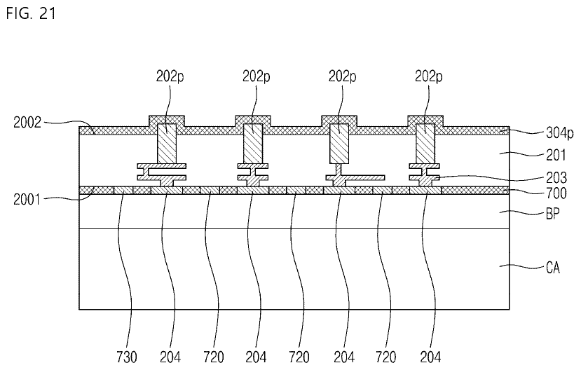

Referring to FIG. 21, a sub-film 304p may be formed on one surface of the semiconductor substrate 201, through which the preliminary through vias 202p are exposed. The sub-film 304p may be conformally formed on one surface of the semiconductor substrate 201 from which the preliminary through vias 202p protrude. For example, the formation of the sub-film 304p may be performed by using a chemical vapor deposition (CVD) process. Therefore, the sub-film 304p may be conformally formed even on the protruding preliminary through vias 202p. The sub-film 304p may include at least one of a silicon oxide, a silicon nitride, or a silicon oxynitride.

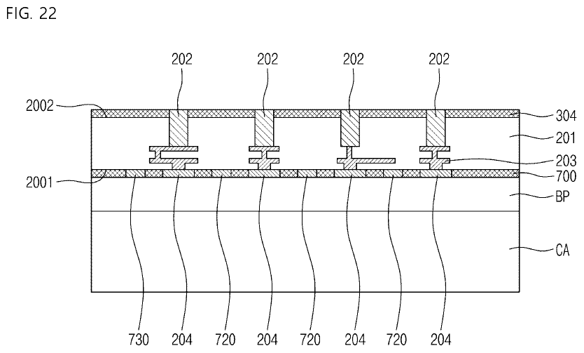

Referring to FIG. 22, the sub-film 304p may be planarized to form the sub-pattern 304. In addition, the preliminary through vias 202p covered by the sub-film 304p may be planarized to form the through vias 202. For example, the planarization of the sub-film 304p may be performed by using an etch-back process or a chemical mechanical polishing (CMP) process. The through vias 202 may be exposed by the sub-pattern 304.

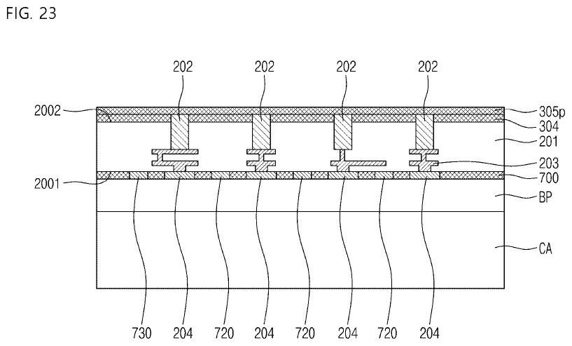

Referring to FIG. 23, a cover film 305p may be formed on the sub-pattern 304. The cover film 305p may also be formed on the exposed through vias 202. The cover film 305p may include a silicon oxide.

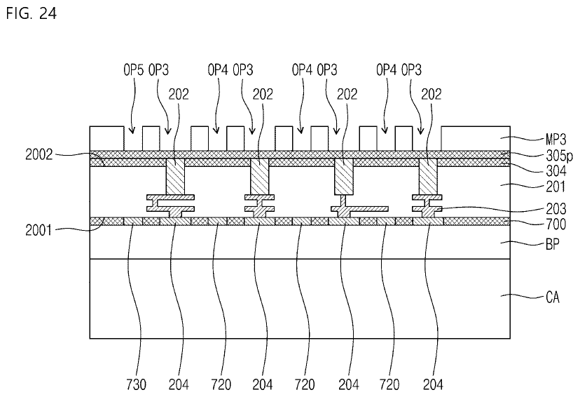

Referring to FIG. 24, a third mask pattern MP3 having third openings OP3 and fourth openings OP4 may be formed on the cover film 305p. The third openings OP3 may define the pad trenches 330 (see FIG. 25). The fourth openings OP4 may define the heat dissipation trenches 310 (see FIG. 25). The fourth openings OP4 may be formed between the third openings OP3.

In one example embodiment, the third mask pattern MP3 may further include a fifth opening OP5. The fifth opening OP5 may define the alignment trench 320 (see FIG. 25).

Referring to FIG. 25, the cover film 305p may be etched by using the third mask pattern MP3 as an etching mask to form the cover pattern 305. Some (e.g., two or more) of the cover film 305p exposed by the third openings OP3 may be etched to form the pad trenches 330. The others of the cover film 305p exposed by the fourth openings OP4 may be etched to form the heat dissipation trenches 310. When the pad trenches 330 are formed, the heat dissipation trenches 310 may also be formed. Thus, levels of bottom surfaces of the heat dissipation trenches 310 may be the same as or substantially similar to levels of bottom surfaces of the pad trenches 330.

The through vias 202 may be exposed by the pad trenches 330. The sub-pattern 304 may be exposed by the pad trenches 330 and the heat dissipation trenches 310.

In one example embodiment, the alignment trench 320 may be further formed by etching the cover film 305p using the third mask pattern MP3 that includes the fifth opening OP5 as an etching mask. When the pad trenches 330 and the heat dissipation trenches 310 are formed, the alignment trench 320 may be formed. Thus, a level of a bottom surface of the alignment trench 320 may be the same as or substantially similar to the levels of the bottom surfaces of the pad trenches 330 and/or the levels of the bottom surfaces of the heat dissipation trenches 310.

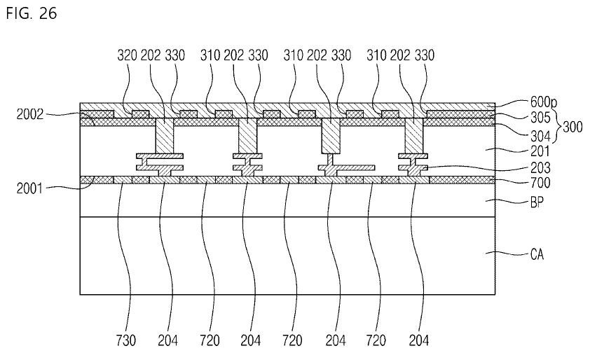

Referring to FIG. 26, a conductive film 600p may be formed on the cover pattern 305. The conductive film 600p may fill the heat dissipation trenches 310 and the pad trenches 330. For example, the conductive film 600p may also be formed on the through vias 202 exposed by the pad trenches 330. The conductive film 600p may also be formed on the sub-pattern 304 exposed by the pad trenches 330 and the heat dissipation trenches 310. In one example embodiment, the conductive film 600p may also fill the alignment trench 320.

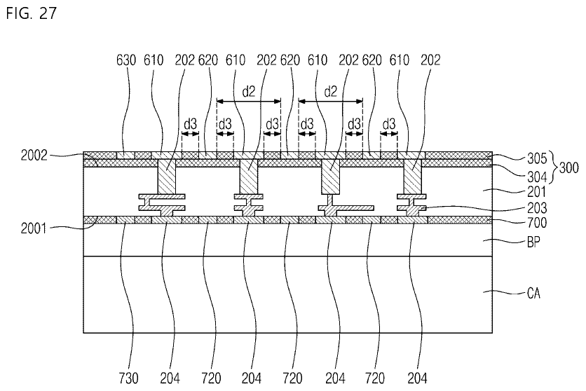

Referring to FIG. 27, the conductive film 600p may be planarized until the cover pattern 305 is exposed to form the back pad structures 610 and the heat dissipation pattern structures 620. For example, the conductive film 600p on the through vias 202 may be planarized to form the back pads 610. The conductive film 600p filling the heat dissipation trenches 310 may be planarized to form the heat dissipation pattern structures 620. Therefore, an upper surface of the cover pattern 305, upper surfaces of the back pads 610, and upper surfaces of the heat dissipation pattern structures 620 may be substantially coplanar.

The heat dissipation pattern structures 620 may be provided between the back pads 610, and spacing distances between the heat dissipation pattern structures 620 and the back pad structures 610 may be substantially the same. For example, the heat dissipation pattern structures 620 may be spaced a third length d3 from the neighboring back pads 610.

Spacing distances between the neighboring heat dissipation pattern structures 620 may be the same as or substantially similar to each other. For example, the neighboring heat dissipation pattern structures 620 may be spaced a second length d2 from each other.

In one example embodiment, the conductive film 600p filling the alignment trench 320 may be planarized to form the alignment key 630. An upper surface of the alignment key 630 may be substantially coplanar with the upper surface of the cover pattern 305.

According to some example embodiments of the present disclosure, a semiconductor package can have improved heat dissipation performance due to heat dissipation patterns extending between through vias. Accordingly, the electrical characteristics of the semiconductor package can be improved.

In addition, according to some example embodiments of the present disclosure, because the heat dissipation patterns are disposed in heat dissipation trenches in a passivation pattern, a contact area between the heat dissipation patterns and the passivation pattern can be increased. Therefore, bonding strength between the heat dissipation patterns and the passivation pattern can be increased and/or structural stability of the semiconductor package can be improved.

In addition, according to some example embodiments of the present disclosure, the heat dissipation patterns are provided on a semiconductor substrate exposed by the heat dissipation trenches, so that the heat dissipation performance of the semiconductor package can be further improved. That is, thermal conductivity between the semiconductor substrate and the heat dissipation patterns can be increased. Therefore, heat accumulated in a semiconductor chip can be more smoothly dissipated. In addition, because the contact area between the heat dissipation patterns and the passivation pattern is increased, the structural stability of the semiconductor package can be improved.

In addition, according to some example embodiments of the present disclosure, the heat dissipation trenches extend into the semiconductor substrate so that the heat dissipation patterns can be provided even in the semiconductor substrate. Accordingly, the thermal conductivity between the semiconductor substrate and the heat dissipation patterns can be increased. In addition, the heat dissipation performance and/or the structural stability of the semiconductor package can be further improved.

In addition, according to some example embodiments of the present disclosure, because the heat dissipation patterns filling the heat dissipation trenches protrude from the passivation pattern, a contact area between an insulating pattern provided between the semiconductor chips and the heat dissipation patterns can be increased. Accordingly, the structural stability of the semiconductor package can be improved.

In addition, according to some example embodiments of the present disclosure, because the heat dissipation patterns extend to cross one surface of the semiconductor substrate and are exposed through side surfaces of the stacked semiconductor chips, heat generated inside the semiconductor chips can be dissipated to the outside through the heat dissipation patterns. Therefore, the heat dissipation performance of the semiconductor package can be improved.

In addition, according to some example embodiments of the present disclosure, because back pads and the heat dissipation patterns are formed together through the same process, a manufacturing method of the semiconductor package can be simplified and/or manufacturing costs can be reduced.

In addition, according to some example embodiments of the present disclosure, because an alignment trench and the heat dissipation trenches are formed together through the same process, the manufacturing method of the semiconductor package can be simplified and/or the manufacturing costs can be reduced.

In addition, according to some example embodiments of the present disclosure, because an alignment key and the heat dissipation patterns are formed together through the same process, the manufacturing method of the semiconductor package can be simplified and/or the manufacturing costs can be reduced.

In addition, according to some example embodiments of the present disclosure, because pad trenches and the heat dissipation trenches are formed together through the same process, the manufacturing method of the semiconductor package can be simplified and/or the manufacturing costs can be reduced.

In addition, according to some example embodiments of the present disclosure, base heat dissipation patterns are provided even on a base chip on which the semiconductor chips are disposed thereby improving electrical characteristics and/or the structural stability of the semiconductor package.

In addition, according to some example embodiments of the present disclosure, because the semiconductor chip includes front heat dissipation patterns corresponding to the heat dissipation patterns and the heat dissipation patterns come into direct contact with the front heat dissipation patterns, bonding strength between the semiconductor chips can be increased. Therefore, the structural stability of the semiconductor package can be improved.

In addition, according to some example embodiments of the present disclosure, because the semiconductor chip includes an additional heat dissipation pattern corresponding to the alignment key and the alignment key comes into direct contact with the additional heat dissipation pattern, the bonding strength between the semiconductor chips can be increased. Therefore, the structural stability of the semiconductor package can be improved.

The above-described contents are specific example embodiments for implementing the present disclosure. In addition to the above-described example embodiments, the present disclosure will also include some example embodiments that modify the above-described example embodiments. In addition, the present disclosure will also include technologies that can be implemented by being easily modified using the above-described example embodiments. Therefore, the scope of the present disclosure should not be limited to the above-described example embodiments, but should be defined not only by the appended claims but also by the equivalents of the claims of the present disclosure.

What is claimed is:

1. A semiconductor package comprising
vertically stacked semiconductor chips including semiconductor chips vertically stacked on each other,
wherein at least one of the semiconductor chips includes
a semiconductor substrate,
a passivation pattern on a first surface of the semiconductor substrate,
through vias in the semiconductor substrate, the through vias passing through the passivation pattern,
back pad structures on the through vias, the back pad structures exposed by the passivation pattern, and
heat dissipation pattern structures between the back pad structures, the heat dissipation pattern structures filling heat dissipation trenches defined in the passivation pattern, respectively, the heat dissipation pattern structures including a same material as the back pad structures.

2. The semiconductor package of claim 1, wherein
the at least one of the semiconductor chips further includes an alignment key filling an alignment trench defined in the passivation pattern, and
a level of a bottom surface of the alignment trench is same as levels of bottom surfaces of the heat dissipation trenches.

3. The semiconductor package of claim 2, wherein
the alignment key includes a same material as the back pad structures.

4. The semiconductor package of claim 2, wherein
the heat dissipation pattern structures and the alignment key are on the passivation pattern.

5. The semiconductor package of claim 2, wherein
the heat dissipation trenches and the alignment trench are recessed from one surface of the passivation pattern to expose the semiconductor substrate, and
the heat dissipation pattern structures and the alignment key are on exposed portions of the semiconductor substrate.

6. The semiconductor package of claim 5, wherein
the heat dissipation trenches and the alignment trench pass through the passivation pattern and are recessed from the first surface of the semiconductor substrate such that bottom surfaces of the heat dissipation trenches and a bottom surface of the alignment trench are in the semiconductor substrate.

7. The semiconductor package of claim 6, wherein
the at least one of the semiconductor chips further includes barrier patterns provided between the heat dissipation pattern structures and the semiconductor substrate and between the alignment key and the semiconductor substrate.

8. The semiconductor package of claim 1, wherein
the heat dissipation pattern structures extend from the first surface of the semiconductor substrate to a second surface of the semiconductor substrate, the first surface of the semiconductor substrate and the second surface of the semiconductor substrate being opposite to each other, the heat dissipation pattern structures crossing the first surface of the semiconductor substrate.

9. The semiconductor package of claim 8, wherein
the heat dissipation pattern structures are exposed through side surfaces of the vertically stacked semiconductor chips.

10. The semiconductor package of claim 1, wherein
the passivation pattern includes pad trenches, the pad trenches recessed from one surface of the passivation pattern and exposing the through vias,
the back pad structures fill the pad trenches, respectively, and
levels of bottom surfaces of the pad trenches are same as levels of bottom surfaces of the heat dissipation trenches.

11. The semiconductor package of claim 1, wherein
spacing distances between the heat dissipation pattern structures and the back pad structures are same.

12. The semiconductor package of claim 1, wherein
the at least one of the semiconductor chips includes front pads, the front pads electrically connected to the through vias and being on a second surface of the semiconductor substrate that is opposite to the first surface of the semiconductor substrate.

13. The semiconductor package of claim 12, wherein
the at least one of the semiconductor chips includes
front heat dissipation patterns between the front pads, and
a front passivation pattern on the second surface of the semiconductor substrate, the front passivation pattern exposing the front pads and the front heat dissipation patterns,
the front pads of the at least one of the semiconductor chips are in direct contact with the back pad structures of another one of the semiconductor chips, and
the front heat dissipation patterns of the at least one of the semiconductor chips are in direct contact with the heat dissipation pattern structures of the another one of the semiconductor chips.

14. The semiconductor package of claim 1, further comprising:
a base chip under the vertically stacked
semiconductor chips,
wherein the base chip includes
a base substrate,
a base passivation pattern on one surface of the base substrate,
base vias in the base substrate, the base vias passing through the base passivation pattern,
base back pad structures on the base vias exposed by the base passivation pattern, and
base heat dissipation pattern structures between the base back pad structures, the base heat dissipation pattern structures filling base heat dissipation trenches defined in the base passivation pattern, respectively, the base heat dissipation pattern structures including a same material as the base back pad structures.

15. A method of manufacturing a semiconductor package, comprising:
preparing a semiconductor die having through vias;
etching the semiconductor die to expose the through vias;
forming a passivation film on the semiconductor die so that the through vias are exposed through the passivation film;
forming heat dissipation trenches in the passivation film by performing an etching process;
forming back pad structures on the through vias; and
forming heat dissipation pattern structures to fill the heat dissipation trenches,
wherein the forming the back pad structures and the forming the heat dissipation pattern structures are simultaneously performed.

16. The method of claim 15, wherein
the forming the heat dissipation trenches includes
forming a first mask pattern including first openings defining the heat dissipation trenches and a second opening defining an alignment trench on the passivation film, and
forming the heat dissipation trenches and the alignment trench by etching the passivation film using the first mask pattern as an etching mask.

17. The method of claim 16, further including
planarizing the passivation film to form a planarized passivation film, the planarized passivation film exposing the through vias,
wherein the forming the back pad structures includes
forming a conductive film on the planarized passivation film, the conductive film filling the heat dissipation trenches and the alignment trench,
forming a second mask pattern having pad openings vertically overlapping the through vias, heat dissipation openings vertically overlapping the heat dissipation trenches, and an alignment opening vertically overlapping the alignment trench on the conductive film,
forming conductive patterns on the conductive film exposed by the pad openings, the heat dissipation openings, and the alignment opening, and
forming the back pad structures, the heat dissipation pattern structures, and an alignment key by etching the conductive film using the conductive patterns as an etching mask.

18. The method of claim 15, wherein
the forming the heat dissipation trenches includes
forming a third mask pattern including third openings and fourth openings, the third openings defining pad trenches that expose the through vias, the fourth openings defining the heat dissipation trenches on the passivation film, and
forming the heat dissipation trenches and the pad trenches by etching the passivation film using the third mask pattern as an etching mask.

19. The method of claim 18, wherein
the third mask pattern further includes a fifth opening defining an alignment trench, and
when the heat dissipation trenches and the pad trenches are formed by etching the passivation film using the third mask pattern as the etching mask, the alignment trench is further formed.

20. The method of claim 18, wherein
the forming the back pad structures includes
forming a conductive film on the passivation film on which the heat dissipation trenches and the pad trenches are formed, and
forming the heat dissipation pattern structures and the back pad structures by planarizing the conductive film until the passivation film is exposed.
